(19) United States
(12) Patent Application Publication
(10) Pub. No.: US 2025/0305130 A1
(43) Pub. Date: Oct. 2, 2025

(54) Ultrasonic Assisted Decomposition System

(71) Applicant: Applied Materials, Inc., Santa Clara, CA (US)

(72) Inventors: Jing Zheng, Santa Clara, CA (US); Muhannad Mustafa, Milpitas, CA (US); Aditya Chuttar, Sunnyvale, CA (US); Srinivas Gandikota, Santa Clara, CA (US); Yixiong Yang, Fremont, CA (US); Kevin Griffin, Livermore, CA (US); Hsin-Jung Yu, Santa Clara, CA (US)

(73) Assignee: Applied Materials, Inc., Santa Clara, CA (US)

(21) Appl. No.: 19/074,535

(22) Filed: Mar. 10, 2025

Related U.S. Application Data
(60) Provisional application No. 63/571,977, filed on Mar. 29, 2024.

(51) Int. Cl. C23C 16/455

(52) U.S. Cl. CPC C23C 16/45527; C23C 16/45544

(57) ABSTRACT

Semiconductor manufacturing processing chambers with ultrasonic transducers connected to ultrasonic conductor rods and methods of use are described. A vibrating web or membrane connected to the ultrasonic conductor rod transfers ultrasonic vibrations generated by the ultrasonic transducer into a gas in a gas box plenum or in the gas inlet to create perturbations in the process gas.

### CROSS-REFERENCE TO RELATED APPLICATIONS

The present application claims priority to U.S. provisional application Ser. No. 63/571,977, filed on Mar. 29, 2024, the entire content of which is incorporated herein by reference.

### TECHNICAL FIELD

Embodiments of the disclosure are directed to semiconductor manufacturing processing chamber with ultrasonics. In particular, embodiments of the disclosure are directed to semiconductor manufacturing processing chambers and processing methods using ultrasonic waves.

### BACKGROUND

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The various semiconductor components (e.g., interconnects, vias, capacitors, transistors) require precise placement of high aspect ratio features. Reliable formation of these components is critical to further increases in device and density.

Additionally, the electronic device industry and the semiconductor industry continue to strive for larger production yields while increasing the uniformity of layers deposited on substrates having increasingly larger surface areas. These same factors in combination with new materials also provide higher integration of circuits per unit area on the substrate.

As the dimensions of devices continue to shrink, new methods and precursors are developed to improve film uniformity and increase the device yield. There is increasing interest in the use of large molecule organic precursors for film deposition by thermal decomposition. However, many of these large organic molecules thermally decompose slowly or inefficiently resulting in a low deposition rate using current hardware configurations.

Possible solutions to improve decomposition efficiency include elevated temperatures and plasma-enhanced techniques. Both elevated temperature processes and plasma-enhanced processes can result in damage to existing materials on the substrate surface or push against the thermal budget for the device being formed.

Accordingly, there is a need in the art for improved methods and apparatus to increase decomposition for large organic molecules.

### SUMMARY

One or more embodiments of the disclosure are directed to a semiconductor manufacturing process chamber including: a chamber body having a bottom, a sidewall and a lid enclosing an interior volume; a gas distribution assembly on the chamber lid, the gas distribution assembly including a backing plate and a showerhead, the backing plate having a inlet opening extending through the backing plate, and a contoured front surface extending from the inlet opening to an outer peripheral portion of the front surface of the backing plate, the backing plate adjacent to the showerhead so that a plenum is formed between the front surface of the backing plate and a back surface of the showerhead; and an ultrasonic transducer connected to an ultrasonic conductor rod, the ultrasonic transducer configured to generate ultrasonic vibrations that affect a gas within the plenum, for example accelerating decomposition of the gas.

In some aspects, the techniques described herein relate to a semiconductor manufacturing process chamber including: a chamber body having a bottom, a sidewall and a lid enclosing an interior volume; a gas distribution assembly on the chamber lid, the gas distribution assembly including a backing plate and a showerhead, the backing plate having a inlet opening extending through the backing plate, and a contoured front surface extending from the inlet opening to an outer peripheral portion of the front surface of the backing plate, the backing plate adjacent to the showerhead so that a plenum is formed between the front surface of the backing plate and a back surface of the showerhead; a gas insert on the backing plate, the gas insert having an opening extending from a top surface to a bottom surface of the gas insert, the opening aligned with the opening in the backing plate; and an ultrasonic transducer on the gas insert.

In some aspects, the techniques described herein relate to a method of depositing a film including: flowing a process gas into a process region of a process chamber; and providing vibrational energy to the process gas using an ultrasonic transducer with an ultrasonic conductor rod extending therefrom.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

The shading used in the Figures is for descriptive purposes only and should not be taken as referring to a particular material of construction. The cross-hatching patterns are solely chosen to help illustrate the different components and unless otherwise noted, the various materials of construction of the different components can be the same or different.

FIG. 1 illustrates a schematic representation of a processing chamber according to one or more embodiments of the disclosure;

FIG. 2 illustrates a schematic representation of a processing chamber with ultrasonic transducer connected to a vibrating web in the gas box plenum according to one or more embodiments of the disclosure; and

FIG. 3 illustrates a schematic representation of a processing chamber with ultrasonic transducer connected to a membrane in the gas insert according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to a process comprising the sequential exposure of two or more reactive compounds to deposit a layer of material on a substrate surface. “Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

In some embodiments, the deposition method is a decomposition process. For example, elevated temperatures result in degradation of the precursor compound to form a film on the substrate, rather than an electrochemical reduction or other reaction process.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Decomposition reactions can have varying efficiencies and temperature requirements. The inventors have found that the low-efficiency decomposition of large molecules based organic precursors, which causes low deposition rate in current hardware, can be improved using ultrasonics. According to one or more embodiments, “large molecule” and “large organic molecule” refers to a molecule including more than one carbon atom. For example, CH₄ is not a large organic molecule, but C₂H₂, C₃H₆ and molecules containing greater than one carbon atom are considered “large organic molecules.” Some embodiments of the disclosure advantageously accelerate the decomposition process to target precursor chemical molecules, while minimizing hardware consumption in terms of material and power waste. According to one or more embodiments, “accelerate” refers to increasing a decomposition rate of a precursor, for example, a large molecule precursor during a film formation process compared to a film formation process that does not utilize ultrasonic vibration to decompose the precursor. In one or more embodiments, the accelerated decomposition of the precursor increases the deposition rate of a film formed from the precursor compared to a process that does not use ultrasonic vibration to decompose the precursor.

One or more embodiments of the disclosure provide hardware with an ultrasonic transducer, electrical controller for the transducer, a vibration wave conductor, and, optionally, an ultrasonic damping module. In some embodiments, the ultrasonic transducer advantageously provides ultrasonic waves that accelerate the decomposition of a target gas phase precursor. The controller of some embodiments advantageously controls and regulates the actuation of the transducer. The conductor can include a structure that transfers the ultrasonic vibrations from the generator into the reaction chamber. The optional damping module of some embodiments includes a seal and housing structure that isolates the ultrasonic vibrations from other hardware.

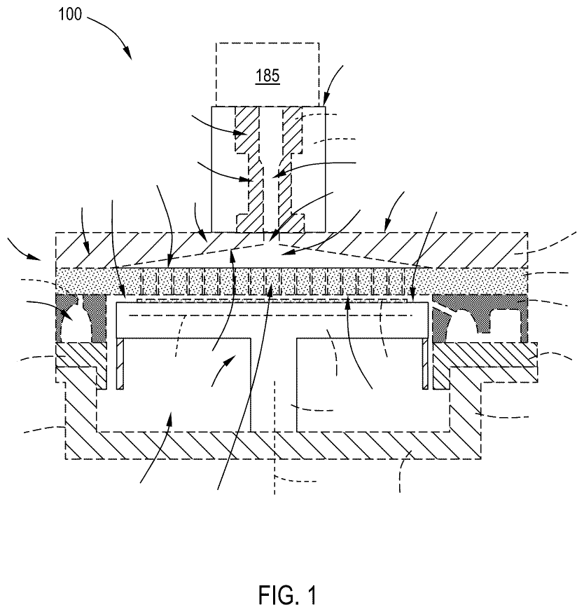

FIG. 1 illustrates an embodiment of a semiconductor manufacturing processing chamber 100. The semiconductor manufacturing processing chamber 100 comprises a chamber body 101 having sidewalls 102 and a bottom 103 surrounding an interior volume 105. The sidewall 102 and bottom 103 can be integrally formed or separate component connected together by any suitable connection or fastener.

The semiconductor manufacturing processing chambers 100 of some embodiments includes a gas distribution assembly 110. The gas distribution assembly 110 comprises a backing plate 120 and a faceplate 130. In some embodiments, the semiconductor manufacturing process chamber 100 further comprises a pumping ring 140. In some embodiments, the pumping ring 140 is considered a separate part from the gas distribution assembly 110.

Chamber body 101, in conjunction with the gas distribution assembly 110 encloses the interior volume 105 of the semiconductor manufacturing processing chamber 100. During processing, the interior volume 105 of the semiconductor manufacturing processing chamber 100 is typically maintained at a controlled pressure (usually a low-pressure environment) using one or more gas inlet (not shown) and one or more exhaust (not shown). The skilled artisan will be familiar with the general construction of the chamber body 101 and the use of gas inlets and exhaust systems.

The backing plate 120 has a front surface 121 and a back surface 122 that define a thickness of the backing plate 120. The backing plate 120 has an inner portion 124 and an outer portion 125. The backing plate 120 contacts the faceplate 130 at the outer portion 125.

The backing plate 120 has an inlet opening 123 in a center thereof. The inlet opening 123 extends through the thickness of the backing plate 120 from the back surface 122 to the front surface 121. The central axis of the backing plate 120 is defined at the center of the inlet opening 123. The outer peripheral edge of the inner portion 124 of the front surface 121 of some embodiments is concentric with the inlet opening 123. While the backing plate 120 of some embodiments has an oblong or non-symmetrical shape, the central axis is considered to be at the center of the inlet opening 123 even if that is not the center of mass of the backing plate 120.

The front surface 121 of the backing plate 120 at the inner portion 124 has a concave shape. The concave shape of some embodiments has a linear slope from the inlet opening 123 to the outer peripheral edge of the inner portion 124 at the transition to the outer portion 125, as illustrated in the Figures. In some embodiments, the concave shape has a curved profile from the inlet opening 123 to the outer peripheral edge of the inner portion 124.

The gas distribution assembly 110 includes a faceplate 130, which may also be referred to as a “showerhead”. The faceplate 130 has a front surface 131 and a back surface 132 defining a thickness of the faceplate 130. The faceplate 130 has an inner portion 133 and an outer portion 134. The inner portion 133 of the faceplate 130 aligns with the inner portion 124 of the backing plate 120 and the outer portion 134 of the faceplate 130 aligns with the outer portion 125 of the backing plate 120. The inner portion 133 of the faceplate 130 comprises a plurality of apertures 135 extending through the thickness of the faceplate 130.

The backing plate 120 can be connected to the faceplate 130 by any suitable mechanism. For example, the backing plate 120 can be welded to the faceplate 130. In some embodiments, the backing plate 120 is connected to the faceplate 130 with a plurality of fasteners. Suitable fasteners include, but are not limited to, bolts with or without O-rings.

When the front surface 121 of the outer portion 125 of the backing plate 120 is in contact with the outer portion 134 of the back surface 132 of the faceplate 130, a gas box plenum 129 is formed in the space between the front surface 121 of the inner portion 124 of the backing plate 120 and the inner portion 133 of the back surface 132 of the faceplate 130.

In some embodiments, the gas box plenum 129 has a coating to improve chemical compatibility. In some embodiments, the coating covers the entire front surface 121 of the backing plate 120 and the entire back surface 132 of the faceplate 130, including in the inlet opening 123 of the backing plate 120 and the plurality of apertures 135 of the faceplate 130. In some embodiments, the coating is only on the portions of the backing plate 120 and faceplate 130 that will come into contact with the process gases.

In some embodiments, the gas distribution assembly 110 further comprises a cap housing 150 connected to the back surface 122 of the backing plate 120. The cap housing 150 has a gas insert 160 with an inner channel 162 aligned with the inlet opening 123 in the center of the backing plate 120. The inner channel 162 of some embodiments has an upper portion 164 and a lower portion 166. The upper portion 164 has a larger inner diameter than the inner diameter of the lower portion 166.

Some embodiments of the semiconductor manufacturing processing chamber 100 include a pumping ring 140 positioned on a top surface of a choke plate 155. The pumping ring 140 has a front surface and a back surface defining a thickness of the pumping ring 140. In use, the back surface of the pumping ring 140 is positioned adjacent to or in contact with the front surface 131 of the faceplate 130. In some embodiments, in use, the front surface of the pumping ring 140 is positioned in contact with the top surface of the choke plate 155.

The pumping ring 140 of some embodiments comprises a vacuum plenum configured to remove process gases from an interior of the processing chamber. The vacuum plenum is formed by the recess in the front surface of the pumping ring 140 when the front surface of the pumping ring 140 is adjacent another surface. For example, as shown in FIG. 1, when the pumping ring 140 is positioned so that the front surface is adjacent to or in contact with the choke plate 155 or chamber sidewall 102 so that a pumping volume 145 is formed.

In some embodiments, the pumping ring 140 is connected to the backing plate 120 with a plurality of fasteners (not shown) that extend through the faceplate 130. In some embodiments, bolting the backing plate 120 to the pumping ring 140 sandwiches the faceplate 130 between the backing plate 120 and the pumping ring 140.

In some embodiments, at least one aperture 146 extends between the recess in the front surface of the pumping ring 140 and the back surface 142 of the pumping ring 140. In some embodiments, the at least one aperture 146 extends between the pumping volume 145 in the front surface of the pumping ring 140 and an inner face of the pumping ring 140.

During use, the backing plate 120, faceplate 130 and pumping ring 140, in addition to other components, may be separated by one or more O-rings (not shown) to help maintain a fluid-tight seal for the processing chamber. In some embodiments, the gas distribution assembly 110 includes a plurality of O-rings positioned between the backing plate 120 and the faceplate 130 and/or a plurality of O-rings positioned between the faceplate 130 and the pumping ring 140. In some embodiments, the pumping ring 140 is connected to the choke plate 155 with at least one O-ring positioned between.

The semiconductor manufacturing processing chamber 100 comprises a substrate support 170 within the chamber interior volume 105. The substrate support 170 of some embodiments comprises a support body 171 positioned on a support shaft 172. The support body 171 has a support surface 173 configured to support a semiconductor wafer 108 for processing. The support shaft 172 of some embodiments is configured to move the support body 171 closer to/further from the faceplate 130 and/or around a rotational axis 175 of the support shaft 172. During processing, the support surface 173 is spaced from the front surface 131 of the faceplate 130 to form a process gap providing the process region 109.

In some embodiments, the support body 171 includes a thermal element 174 configured to heat the semiconductor wafer 108 on the support surface 173. The thermal element 174 can be any suitable heating mechanism. For example, in some embodiments, the thermal element 174 comprises a resistive heating element that is connected to a power supply (not shown) configured to apply power to the thermal element 174 to heat the support body 171. In some embodiments, the support body 171 includes an electrostatic chuck (ESC) (not shown). The skilled artisan will be familiar with the construction of the ESC and the manner in which the ESC is powered and employed.

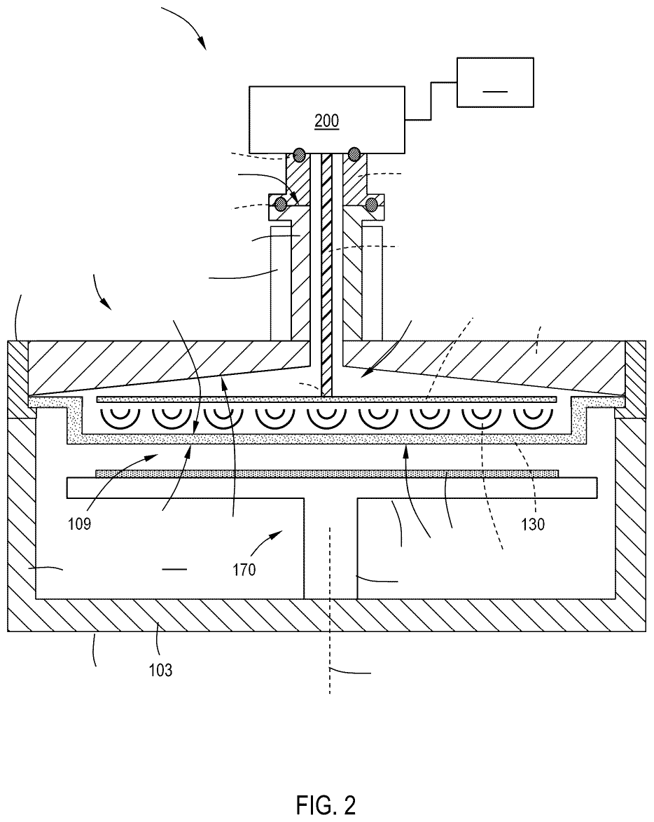

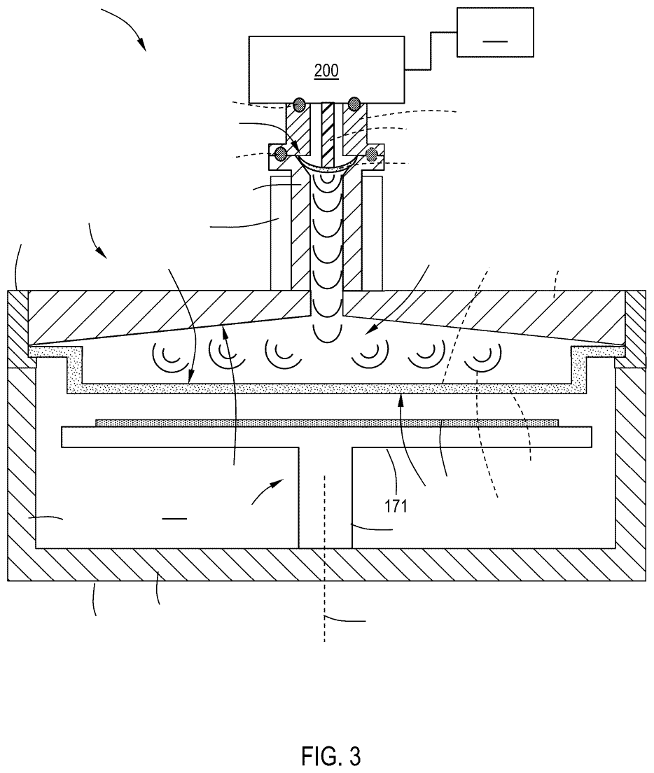

In some embodiments, as shown in FIG. 1, a gas source 185 is positioned on the gas insert 160. The gas source 185 of some embodiments comprises a remote plasma source (RPS). In some embodiments, the gas source 185 is replaced with an ultrasonic transducer, as shown in FIGS. 2 and 3.

Referring to FIGS. 2 and 3, one or more embodiments of the disclosure are directed to semiconductor manufacturing process chambers 100 comprising a chamber body 101 having a bottom 103, a sidewall 102 and a lid 104 enclosing an interior volume 105.

A gas distribution assembly 110 is positioned on the chamber lid 104, the gas distribution assembly comprising a backing plate 120 and a showerhead or faceplate 130. The backing plate 120 has an inlet opening 123 extending through the backing plate 120 and a contoured front surface 121 extending from the inlet opening 123 to an outer peripheral portion of the front surface 121 of the backing plate 120. The backing plate 120 is adjacent to the showerhead or faceplate 130 so that a gas box plenum 129 is formed between the front surface 121 of the backing plate 120 and a back surface 132 of the showerhead or faceplate 130.

An ultrasonic transducer 200 is connected to the gas insert 160 and/or the cap housing 150. The ultrasonic transducer 200 can be any suitable component that is configured to generate ultrasonic vibrations that can affect a gas within the gas box plenum 129. In one or more embodiments, a controller 205 is connected to the ultrasonic transducer 200 to provide power and control the parameters (e.g., vibration frequency) of the ultrasonic transducer 200.

The ultrasonic transducer 200 is connected to an ultrasonic conductor rod 210. The ultrasonic conductor rod 210 extends from the ultrasonic transducer 200 into the inner channel 162 of the gas insert 160. As shown in the embodiment of FIG. 2, the ultrasonic conductor rod 210 extends through the gas insert 160, the inlet opening 123 of the backing plate 120 and into the gas box plenum 129 between the backing plate 120 and the faceplate 130.

In some embodiments, the semiconductor manufacturing processing chamber 100 further comprises an ultrasonic damping adapter 220 positioned between the top surface 161 of the gas insert 160 and the ultrasonic transducer 200. The ultrasonic damping adapter 220 can be made from any suitable material that can prevent or minimize vibrations from the ultrasonic transducer 200 from impacting the other hardware components of the semiconductor manufacturing processing chamber 100 that are not part of the ultrasonic vibration system.

The ultrasonic damping adapter 220 of some embodiments is further isolated from the ultrasonic transducer 200 and the gas insert 160 using a plurality of O-rings 222

In the embodiment illustrated in FIG. 2, the semiconductor manufacturing processing chamber 100 further comprises a vibrating web 230. In some embodiments, the vibrating web 230 is connected to the bottom end 212 of the ultrasonic conductor rod 210. The vibrating web 230 of some embodiments comprises a plurality of openings that allow a gas to pass through the vibrating web 230 so that the gas flow is not unnecessarily restricted by the vibrating web 230.

In some embodiments, the vibrating web 230 is positioned within the gas box plenum 129 between the backing plate 120 and the faceplate 130. In some embodiments, the vibrating web 230 comprises a disk-shaped body with an outer diameter in the range of 50% to 95% of an outer diameter of the contoured front surface of the backing plate.

In use, ultrasonic vibrations generated by the ultrasonic transducer 200 are transmitted to the vibrating web 230 through the ultrasonic conductor rod 210 to transfer vibrational energy to the gas box plenum 129 to cause perturbations (vibrational energy 225) in the gas within the gas box plenum 129.

FIG. 3 illustrates another embodiment of the disclosure in which the ultrasonic conductor rod 210 is connected to the ultrasonic transducer 200 and extends into an upper portion 164 of the gas insert 160. A membrane 240 is connected to bottom end 212 of the ultrasonic conductor rod 210. The membrane 240 can be made of any suitably flexible material that can transfer vibrational energy from the ultrasonic transducer 200 through the ultrasonic conductor rod 210 into the membrane 240.

In the illustrated embodiment, the upper portion 164 of the gas insert 160 has a chamfered or tapered profile to create a pocket or recessed region in which the membrane 240 can be positioned.

In some embodiments, the membrane 240 is made of a material that is gas-tight to prevent gases from flowing through the 240. In some embodiments, the cap housing 150 is configured to provide a flow of gas into the inlet opening 123 in the gas insert 160 below the membrane 240. The ultrasonic transducer 200 is configured to transfer vibrational energy 225 into the gas in the opening in the gas insert 160 and into the gas box plenum 129 between the backing plate 120 and the faceplate 130.

One or more embodiments of the disclosure are directed to methods of depositing a film. A process gas is flowed into a process region 109 of a process chamber. Vibrational energy 225 is provided to the process gas using an ultrasonic transducer 200 with an ultrasonic conductor rod 210 extending therefrom. In some embodiments, the vibrational energy 225 is transferred to a vibrating web 230 positioned within the gas box plenum 129 between the backing plate 120 and the faceplate 130, as shown in FIG. 2. In some embodiments, the vibrational energy 225 is transferred to a gas in the gas insert 160 using a membrane 240 positioned at the upper portion of the gas insert 160, as shown in FIG. 3.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A semiconductor manufacturing process chamber comprising:
a chamber body having a bottom, a sidewall and a chamber lid enclosing an interior volume;
a gas distribution assembly on the chamber lid, the gas distribution assembly comprising a backing plate and a showerhead, the backing plate having a inlet opening extending through the backing plate, and a contoured front surface extending from the inlet opening to an outer peripheral portion of the contoured front surface of the backing plate, the backing plate adjacent to the showerhead so that a plenum is formed between the front surface of the backing plate and a back surface of the showerhead; and
an ultrasonic transducer connected to an ultrasonic conductor rod, the ultrasonic transducer configured to generate ultrasonic vibrations that affect a gas within the plenum.

2. The semiconductor manufacturing process chamber of claim 1, further comprising:
a cap housing on the backing plate, the cap housing having a bottom surface in contact with a back surface of the backing plate, and an opening extending through a length of the cap housing from a top surface to the bottom surface, the opening positioned over the opening of the backing plate;
a gas insert within the opening in the cap housing, the gas insert having an opening extending from a top surface of the gas insert to a bottom surface of the gas insert, the opening aligned with the opening in the backing plate; and
an ultrasonic damping adapter positioned between the top surface of the gas insert and the ultrasonic transducer.

3. The semiconductor manufacturing process chamber of claim 2, wherein the ultrasonic conductor rod extends from the ultrasonic transducer through the opening in the gas insert and the opening in the backing plate.

4. The semiconductor manufacturing process chamber of claim 3, further comprising a vibrating web connected to a bottom end of the ultrasonic conductor rod.

5. The semiconductor manufacturing process chamber of claim 4, wherein the vibrating web is positioned within the plenum.

6. The semiconductor manufacturing process chamber of claim 5, wherein the vibrating web is a disk with an outer diameter.

7. The semiconductor manufacturing process chamber of claim 6, wherein the outer diameter of the vibrating web is in a range of 50% to 95% of an outer diameter of the contoured front surface of the backing plate.

8. The semiconductor manufacturing process chamber of claim 6, wherein ultrasonic vibration generated by the ultrasonic transducer vibrates the vibrating web through the ultrasonic conductor rod to transfer vibrational energy to a gas in the plenum.

9. The semiconductor manufacturing process chamber of claim 8, further comprising a support assembly positioned within the interior volume of the chamber body, the support assembly comprising a support shaft and a support body base, the support base positioned on a top end of the support shaft and having a support surface configured to hold a wafer during processing, the support surface spaced a distance from the contoured front surface of the showerhead to form a process region.

10. The semiconductor manufacturing process chamber of claim 1 further comprising
a gas insert on the backing plate, the gas insert having an opening extending from a top surface to a bottom surface of the gas insert, the opening aligned with the opening in the backing plate.

11. The semiconductor manufacturing process chamber of claim 10, the ultrasonic conductor rod extending into an upper portion of the gas insert.

12. The semiconductor manufacturing process chamber of claim 11, further comprising a membrane within the upper portion of the gas insert, the membrane connected to the ultrasonic conductor rod.

13. The semiconductor manufacturing process chamber of claim 12, wherein the membrane is positioned within a chamfered portion of the upper portion of the gas insert.

14. The semiconductor manufacturing process chamber of claim 12, further comprising:
a cap housing on the backing plate, the cap housing having a bottom surface in contact with a back surface of the backing plate, and an opening extending through a length of the cap housing from a top surface to the bottom surface, the gas insert positioned within the opening in the cap housing, the cap housing configured to provide a flow of a gas into the opening in the gas insert below the membrane.

15. The semiconductor manufacturing process chamber of claim 14, wherein the ultrasonic transducer is configured to transfer vibrational energy into the gas in the opening in the gas insert and into the plenum.

16. The semiconductor manufacturing process chamber of claim 12, further comprising an ultrasonic damping adapter positioned between the top surface of the gas insert and the ultrasonic transducer, the ultrasonic damping adapter configured to minimize vibrational energy from the ultrasonic transducer from transferring to the gas insert, the ultrasonic conductor rod extending through the ultrasonic damping adapter.

17. The semiconductor manufacturing process chamber of claim 16, further comprising a support assembly positioned within the interior volume of the chamber body, the support assembly comprising a support shaft and a support body base, the support base positioned on a top end of the support shaft and having a support surface configured to hold a wafer during processing, the support surface spaced a distance from the contoured front surface of the showerhead to form a process region.

18. A method of depositing a film comprising:
flowing a process gas into a process region of the semiconductor manufacturing process chamber according to claim 1; and
providing vibrational energy to the process gas using an ultrasonic transducer with an ultrasonic conductor rod extending therefrom.

19. The method of claim 18, wherein the ultrasonic conductor rod has a vibrating web connected to a bottom end of the ultrasonic conductor rod, the vibrating web positioned within a plenum formed between a front surface of a backing plate and a back surface of a showerhead.

20. The method of claim 18, wherein the ultrasonic conductor rod has a membrane connected to a bottom end of the ultrasonic conductor rod, the membrane positioned at an upper portion of a gas insert through which the process gas is flowed.
